(19) United States
(12) Patent Application Publication
(10) Pub. No.: US 2010/0327873 A1
(43) Pub. Date: Dec. 30, 2010

(54) MULTI-DIAGNOSTIC APPARATUS FOR SUBSTRATE-LEVEL MEASUREMENTS

(76) Inventors: Leonid A. Dorf, San Jose, CA (US); Shahid Rauf, Pleasanton, CA (US); Kartik Ramaswamy, San Jose, CA (US); Ken Collins, San Jose, CA (US)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/790,682

(22) Filed: May 28, 2010

Related U.S. Application Data
(60) Provisional application No. 61/181,886, filed on May 28, 2009.

(51) Int. Cl. G01N 27/62; G01R 27/08

(52) U.S. Cl. 324/464; 324/691

(57) ABSTRACT

Described herein is a method and apparatus for diagnosing processing equipment with a multi-diagnostic device. In one embodiment, a multi-diagnostic device is located in a plasma processing environment and includes an electronic circuitry. The device includes a first array of sensors and a second array of sensors. The circuitry is used to simultaneously (or nearly simultaneously) measure the distributions of ion saturation current and the potential at the device using the first array of sensors and to measure resistances of the second array of sensors to determine the distribution of the temperature at the surface of the device.

### RELATED APPLICATION

This application claims the benefit of U.S. Provisional Application Ser. No. 61/181,886, filed on May 28, 2009 the entire contents of which are incorporated by reference.

### TECHNICAL FIELD

Embodiments of the present invention relate to a multi-diagnostic device for device-level measurements in a plasma processing environment.

### BACKGROUND

Many industries employ sophisticated manufacturing equipment that includes multiple sensors, controls, and processing chambers, each of which may be carefully monitored during processing to ensure product quality. For some manufacturing equipment (e.g., semiconductor fabrication equipment) it is expensive and time consuming to completely shut down the equipment for the time necessary to perform calibrations, diagnostics, and determine the source of potential issues. Conventional methods of monitoring and performing diagnostics for processing tools such as plasma etch chambers generally include Langmuir probes. These probes, which provide a single-point measurement, introduce a significant disturbance to the processing plasma because of a supporting, wire-shielding alumina tube protruding deeply into the discharge chamber. Thus, it is difficult to determine non-uniformities and plasma parameters during actual processing conditions because of the disturbance from the probes.

### SUMMARY

Described herein is an apparatus and method for diagnosing processing equipment with a multi-diagnostic device. In one embodiment, a multi-diagnostic device is located in a plasma processing environment, such as a processing chamber. The device includes a first module having an array of sensors with each sensor having planar double probes and a second module having an array of sensors with each sensor having a resistor structure. The device also includes electronic circuitry (e.g., external circuitry or on-board circuitry) that is used to simultaneously (or nearly simultaneously) measure the ion saturation current to the device and device potential distribution using the first module, and resistance of the array of sensors of the second module to determine the temperature at the surface of the device.

### BRIEF DESCRIPTION OF THE DRAWINGS

The present invention is illustrated by way of example, and not by way of limitation, in the figures of the accompanying drawings and in which:

FIG. 1 illustrates one embodiment of a manufacturing machine;

FIG. 2 illustrates a method of characterization of a plasma processing chamber using a multi-diagnostic apparatus in accordance with one embodiment;

FIG. 3 illustrates a top view of a multi-diagnostic device in accordance with one embodiment;

FIG. 4 illustrates a top view of a multi-diagnostic device in accordance with another embodiment;

FIG. 5 illustrates on-board circuitry of a multi-diagnostic device in accordance with one embodiment;

FIG. 6 illustrates timing diagrams for measuring data from a device in accordance with one embodiment;

FIG. 7 illustrates a block diagram of a multi-diagnostic apparatus in accordance with one embodiment; and

FIG. 8 illustrates a diagrammatic representation of a machine in the exemplary form of a computer system within which a set of instructions, for causing the machine to perform any one or more of the methodologies discussed herein, may be executed.

### DETAILED DESCRIPTION

Described herein is an apparatus and method for diagnosing processing equipment with a multi-diagnostic device. In one embodiment, a multi-diagnostic device is located in a plasma processing environment, such as a processing chamber. The device includes a first module having an array of sensors with each sensor having planar double probes and a second module having an array of sensors with each sensor having a resistor structure. The device also includes electronic circuitry (e.g., external circuitry or on-board circuitry) that is used to simultaneously (or nearly simultaneously) measure the ion saturation current to the device and device potential distribution using the first module, and resistance of the array of sensors of the second module to determine the temperature at the surface of the device.

The following description provides details of a manufacturing machine that monitors processes run on manufacturing devices. In one embodiment, the manufacturing machine is for use in the manufacturing of devices (e.g., semiconductor wafers, substrates, liquid crystal displays, reticles). Manufacturing such devices generally requires dozens of manufacturing steps involving different types of manufacturing processes. For example, etching, sputtering, and chemical vapor deposition are three different types of processes, each of which is performed on different chambers of a single machine or on different machines.

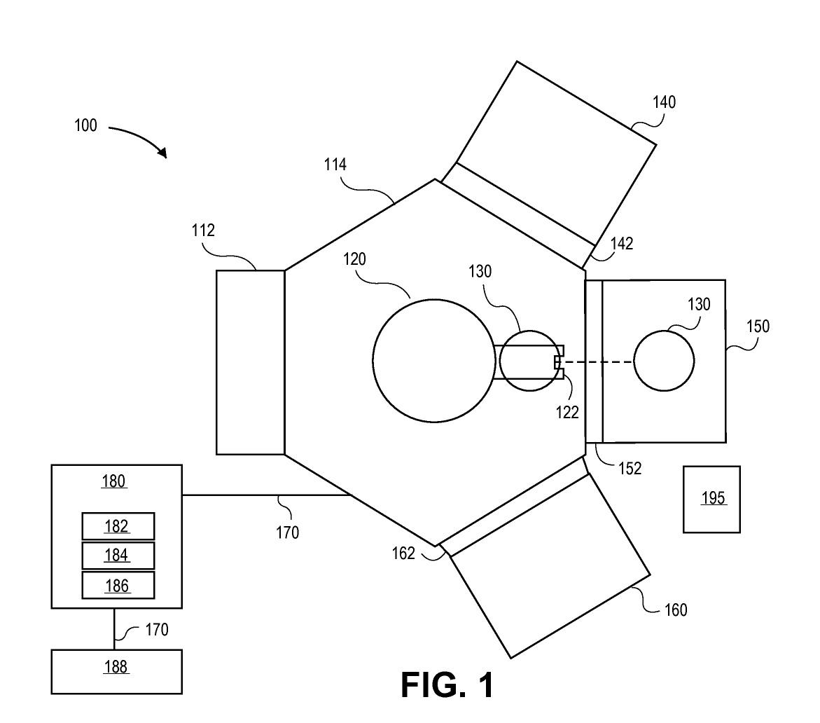

FIG. 1 illustrates one embodiment of a manufacturing machine. The manufacturing machine 100 (e.g., process cluster tool) includes a computing device 180 that includes a processing unit 182, software 184, and memory 186. In one embodiment, the manufacturing machine 100 includes a loading station 112, a robot controller 188, a transfer chamber 114, and chamber ports 142, 152, and 162 associated with processing chambers 140, 150, and 160. The number of processing chamber(s) associated with the transfer chamber can vary. The transfer chamber 114 includes a robot 120, a robot blade 122, and a multi-diagnostic device 130. The transfer chamber 114 is typically held under pressure. A robot controller 188 controls operations of the robot 120 and may be located in the computing device 180, a separate component, or integrated with the robot 120. Data communication links 170 may include conventional communication links, and may be wired or wireless. Data may be transmitted between the transfer chamber 114, process chambers 140, 150, and 160, multi-diagnostic device 130, robot controller 188, and computing device 180 in a raw or processed format.

The robot 120 transfers devices (e.g., semiconductor wafers, substrates, liquid crystal displays, reticles) between the load station 112 and the processing chambers. The chambers 140, 150, and 160 may need plasma diagnostics for a variety of reasons.

In one embodiment, the robot 120 transfers the multi-diagnostic device 130 to at least one processing chamber. The processing chamber may contain processing gases, temperatures, magnetic fields, and pressures at a similar level compared to actual on-line processing conditions. The device 130 is coupled to external circuitry 195 that is used to measure parameters associated with modules located on the device 130. In another embodiment, the external circuitry 195 is replaced with circuitry that is integrated with device 130.

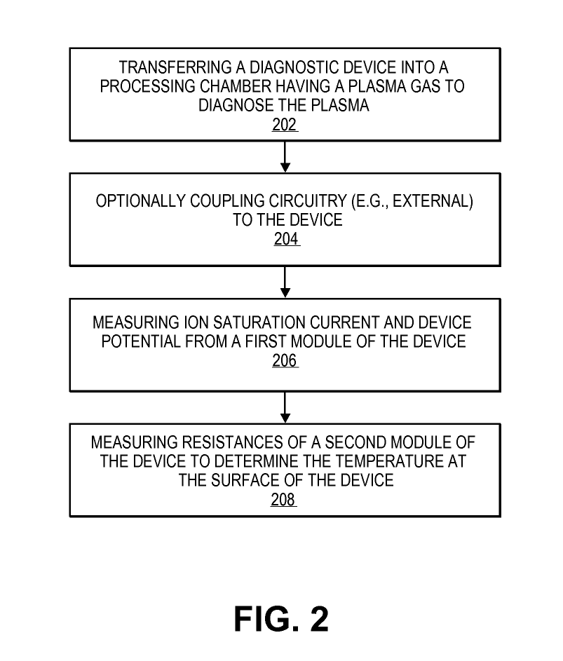

FIG. 2 illustrates a method of characterization of a plasma processing chamber using a multi-diagnostic apparatus in accordance with one embodiment. The apparatus includes a multi-diagnostic device that is located in a plasma processing environment. This device includes a first module having an array of sensors with each sensor having planar double probes. The device also includes a second module having an array of sensors with each sensor having a resistor structure. The method includes transferring the diagnostic device into a processing chamber having a plasma gas to perform diagnosis of the plasma at block 202. Next, the method includes optionally coupling electronic circuitry (e.g., external) to the device at block 204. Alternatively, if the circuitry is on-board the device, then the circuitry is already coupled to the modules. The method further includes measuring ion saturation current to the device and also measuring the device potential from the first module at block 206. The circuitry can measure the ion saturation and the device potential from the first module. The method further includes simultaneously or nearly simultaneously measuring resistances of the array of sensors (each having a resistor structure) of the second module to determine the temperature at the surface of the device at block 208. In this manner, the device is able to simultaneously measure ion saturation current, device potential (e.g., wafer potential, substrate potential), and temperature at the surface of the device from the sensors in order to quickly diagnose and characterize the plasma.

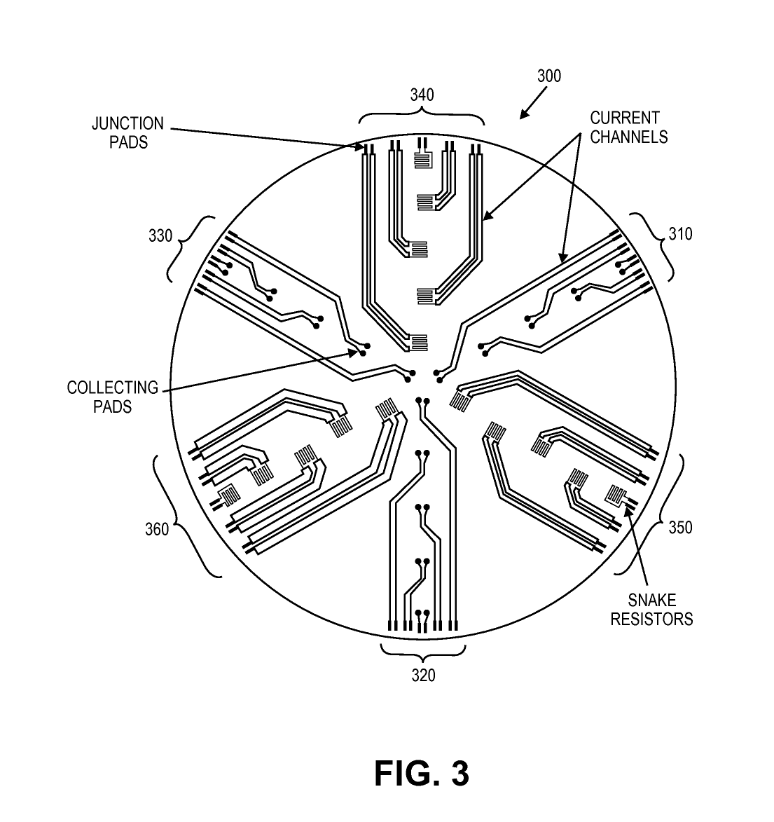

FIG. 3 illustrates a top view of a multi-diagnostic device in accordance with one embodiment. The multi-diagnostic device 300 (e.g., wafer, substrate, liquid crystal display) may be circular, square, rectangular or some other shape.

The device 300 includes a first module (e.g., I-module) that may be repeated multiples times forming an array of sensors 310, 320, and 330. The device 300 includes a second module (e.g., T-module) that may be repeated multiples times forming an array of sensors 340, 350, and 360. The multi-diagnostic device includes two independent modules, the I-module and the T-module.

The I-module includes an array of sensors, which can be planar double probes distributed over the multi-diagnostic device. Each double probe includes two current collecting pads, which are the only elements of the multi-diagnostic device that are directly exposed to plasma. On time-average, the sum of electron, ion, and displacement currents (the latter is essentially the rf current charging and discharging the surface of the multi-diagnostic device from the cathode side) to each pad is equal to zero. However, when an external DC bias (from a floating source) is applied between the two pads, the current balance at each pad is shifted—the pad that is biased more positively, on average collects more electrons, whereas the other pad repels most of the electrons and collects only ions. This results in a non-zero net (dc) current in the double probe circuit. If the applied voltage is sufficiently large (several electron temperatures estimated at the sheath edge), which in practice means several tens of volts, then the current in the electronic circuit will be equal to the ion current to the multi-diagnostic device. Assuming no ionization in the rf sheath, this current is equal to the ion saturation current at the sheath edge. The current in the electronic circuit can be measured, for example, using a shunt resistor. In case of external electronics, it may be connected to the multi-diagnostic device at the wire-joining junction pads illustrated in FIG. 3, which are covered with Kapton tape after the contact is made. In case of on-board electronic circuitry, the contact between the joining pads and the pads on the PCB may be made by means of elastomeric connectors. By directly connecting the wires from the pads to the oscilloscope (using high-voltage oscilloscope probes), or to the differential amplifier on the PCB, one can measure the multi-diagnostic device potential distribution. The design features of the I-module are determined by such factors as robustness, spatial resolution, rf-coupling to plasma, well-defined collection area, sufficiently strong signal, and others. In one embodiment, the multi-diagnostic device does not carry any on-board electronics and relies on external circuitry for measurements. In another embodiment, on-board electronics are integrated with the device.

To interpret Volt-Ampere Characteristics (VAC) of double probes on the substrate, a 2-dimensional fluid plasma model was developed for the CCP chamber with a DC-biased pad on the substrate. This model was used to calculate current at the DC-biased pad versus applied DC voltage, i.e. single probe (SP) VAC. The SP VACs for a variety of discharge rf-voltages and neutral pressures were then used to derive the double probe (DP) VACs, which were in turn analyzed using standard experimental techniques to obtain plasma parameters. Those were found to be in a good agreement with near-sheath plasma parameters calculated self-consistently by the fluid model. Particle-in-cell simulations confirm the results of fluid simulations.

The T-module includes an array of sensors (e.g., snake resistors) distributed over the multi-diagnostic device. Each resistor has an effective length that is much larger than its width and thickness. For a 2 micron thick Aluminum deposition layer, the resistance of each snake resistor (made with 50 micron pitch) at room temperature is estimated to be approximately 1300 Ohm. For a thinner layer, this value is proportionally larger. The resistors have low thermal capacity, which ensures they assume the temperature of the multi-diagnostic device. Operation of the T-module is based on the fact that resistivity of metals changes with temperature.

In one embodiment, for Aluminum in the temperature range of 20-200 degrees (which is typical for the temperature on the surface of the multi-diagnostic device), one can use the following simplified formula: R(T)/R(300K)=1+0.44*(T−300)/100, or 4.4% change in resistivity per 10 degrees change in temperature. In one embodiment, at 150 C, the resistance is ˜1.54 times higher than at the room temperature. The radial temperature profile will be determined by variations of the temperature across the multi-diagnostic device, which can be on the order of a few tens of degrees. This means the values of the snake resistances across the multi-diagnostic device will lie within at least a 10% range, which is far greater than the accuracy of measurements. To monitor resistance variations, a short voltage pulse (from a floating source) with the amplitude, V, on the order of a few volts is applied to each of the resistors. The current, I, through each resistor is then related to its resistance via Ohm's law: R=V/I. For example, a 9V battery voltage results in the current on the order of 7 mA, which can be easily measured using standard multimeters. The connection to the electronics circuitry is made in the same manner as that for the I-module.

In an embodiment, the modules of the device 300 are made with Aluminum physical vapor deposition. The entire device 300, except for the pads, is then coated with polyimide (e.g., 8 um thick). The device 300 is designed for multiple uses in a plasma processing environment. The lifetime of the device will depend upon the conditions of the plasma processing environment.

In some embodiments, the design and the principle of operation of a multi-diagnostic device provides for simultaneous measurements of the temperature, potential, and ion current at the multi-diagnostic device surface.

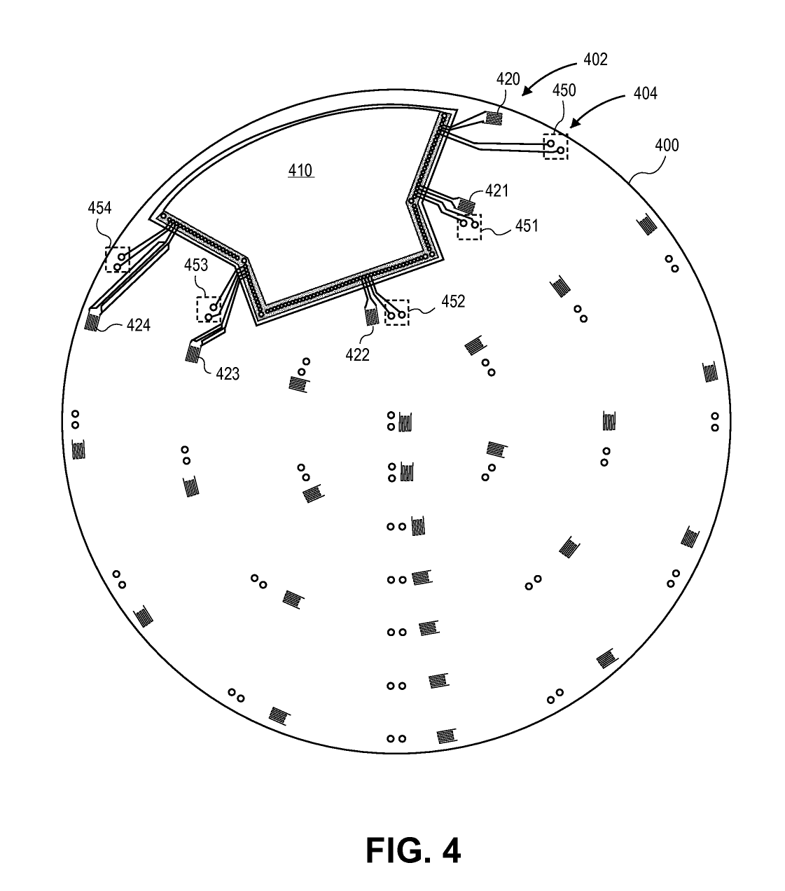

FIG. 4 illustrates a top view of a multi-diagnostic device in accordance with another embodiment. The multi-diagnostic device 400 (e.g., wafer, substrate, liquid crystal display) may be circular, square, rectangular or some other shape. The device 400 includes a first module 404 (e.g., I-module) that may be repeated multiples times to form an array of sensors (e.g., 450-454) spread across a surface of the device 400. In an embodiment, 28 sensors of the I-module are located on the device 400 and coupled to the on-board circuitry 410. FIG. 4 only illustrates the coupling of sensors 450-454 to the on-board circuitry 410 for ease of viewing the sensors on the device 400. The sensors (e.g., 450-454) of the I-module can be planar double probes distributed over the multi-diagnostic device 400. Each double probe includes two current collecting pads, which are the only elements of the multi-diagnostic device that are directly exposed to plasma. Current and voltage characteristics of the device 400 can be measured with these sensors.

The device 400 also includes a second module 402 (e.g., T-module) that may be repeated multiples times forming an array of sensors (e.g., 420-424). The array of sensors, which can be snake resistors, can be distributed over the multi-diagnostic device as illustrated in FIG. 4. In an embodiment, 28 sensors of the T-module are located on the device 400 and coupled to the on-board circuitry 410. FIG. 4 only illustrates the coupling of sensors 420-424 to the on-board circuitry 410 for ease of viewing the sensors on the device 400. Each resistor has an effective length that is much larger than its width and thickness. The resistors have low thermal capacity, which ensures they assume the temperature of the multi-diagnostic device. Operation of the T-module is based on the fact that resistivity of metals changes with temperature.

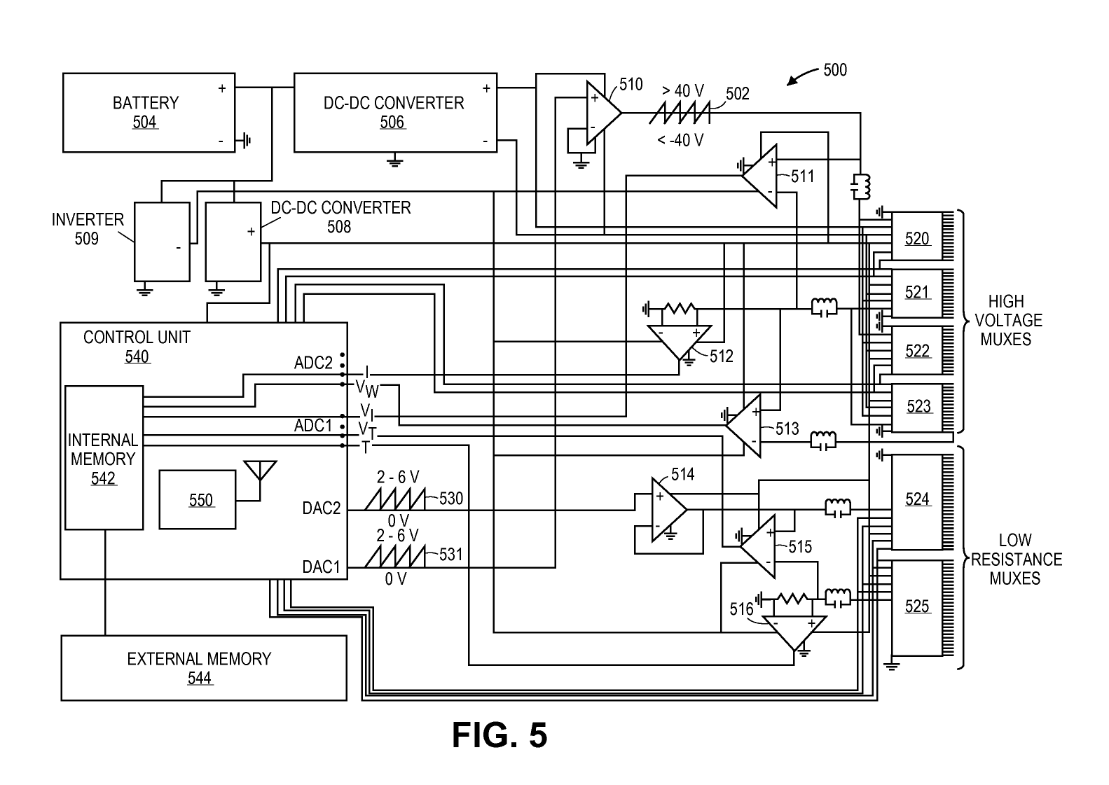

The following exemplifies operation of the on-board circuitry 500 as illustrated in FIG. 5 in accordance with one embodiment. The circuitry 500 may be integrated with various devices (e.g., device 300, device 400) having arrays of sensors. The voltage waveform 502 (e.g., +/−48V at frequency of 700 Hz) is generated using the battery 504, dc-dc converter 506, and operational amplifier (e.g., 510). The circuitry also includes a dc-dc converter 508 and an inverter 509. The multiplexers 520-525 switch applied voltage between pads of various modules (e.g., I-module, T-module, 420-424, 450-454). In one embodiment, the waveform 502 is then delivered to the I-pads on the device through the multiplexers (e.g., 520, 522) that switch the applied voltage between the probes. The probe current is measured using the shunt resistor and the operational amplifier (e.g., 512), and is digitized at a fast rate which provides a sufficient number of points during one voltage ramp (e.g. 200 kS/s) to obtain a detailed and smooth voltage-current characteristic.

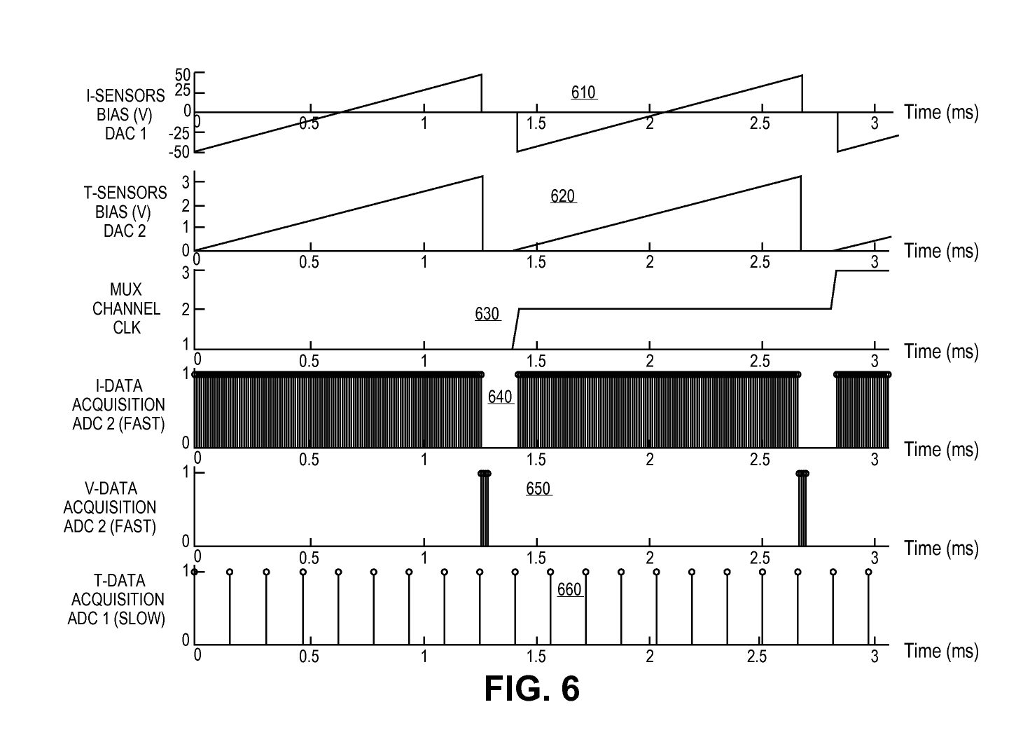

In turn, in an embodiment, a separate voltage waveform (e.g., 530) is applied to the temperature-measuring resistors, and the corresponding current may be digitized at a much lower rate (e.g., each 150 microsec). The voltage of the current pads with respect to a selected pad (e.g., the one in the center), V_{W}, is measured by means of operational amplifiers (e.g., 513) and voltage dividers, when the applied voltage is zero; V_{W} is then digitized, for example, according to the timing diagram illustrated in FIG. 6 in accordance with one embodiment. The applied voltage waveforms may be also measured using operational amplifiers and dividers and may be digitized at the same rate as the T-sensors data. In an embodiment, the circuitry 500 includes operational amplifiers 510-516 for applying waveforms to the modules or for measuring voltage or current characteristics from the modules.

In an embodiment, at 700 Hz biasing frequency, all probes on the wafer (e.g., 28) of each type can be sampled 25 times in one second, thus providing 40 millisecond (ms) time resolution for collected data (i.e., spatial profiles of near-sheath plasma density, electron temperature, wafer voltage, and wafer temperature). The control unit 540 provides synchronous operation of the electronics circuitry by supplying the control logic signals to the corresponding units. The recorded data may be stored on the internal memory 542 or external flash memory chip 544, and then transmitted to a data processing system (e.g, computer system) by using, e.g., a Bluetooth communication unit 550.

FIG. 6 illustrates timing diagrams for measuring data from a device in accordance with one embodiment. The DAC1 of the control unit 540 generates waveform 610 in order to apply a bias voltage to the sensors of the I-modules. The DAC2 of the control unit 540 generates waveform 620 in order to apply a bias voltage to the sensors of the T-modules. The control unit 540 generates a control logic signal 630 for operation of the multiplexers 520-525. The ADC2 of the control unit 540 digitizes I-data 640 acquired from the sensors of the I-modules. The I-data represents ion saturation current to the device. The ADC2 of the control unit 540 also digitizes voltage-data (V-data) 650 acquired from the sensors of the I-modules. The V-data represents a potential distribution of the device. The ADC1 of the control unit 540 digitizes T-data 660 acquired from the sensors of the T-module to determine a temperature at a surface of the device.

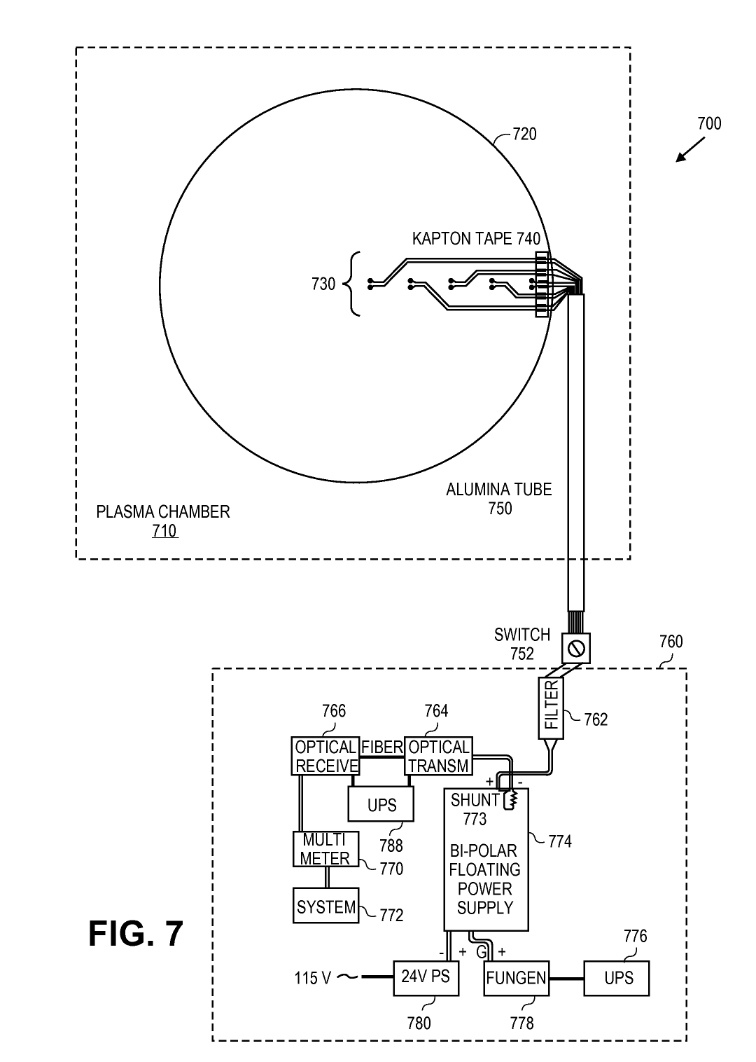

FIG. 7 illustrates a block diagram of a multi-diagnostic apparatus in accordance with one embodiment. The multi-diagnostic apparatus 700 includes a multi-diagnostic device 720 located in a plasma processing chamber 710. The device 700 includes various modules (e.g., I-module, T-module) as discussed herein. External circuitry 760 couples to the module 730 via the switch 752, the alumina tube 750, and the kapton tape 740. The external circuitry 760 performs measurements of the temperature, potential, and ion current at the multi-diagnostic device surface. The external circuitry 760 includes a filter 762, a bi-polar floating power supply 774 having a shunt 773, a power supply 780 (e.g., 24V), a function generator 778, and an uninterruptible power supply (UPS) 476. The circuitry 460 also includes an optical transmitter 464, an UPS 468, an optical receiver 466, a multimeter 470, and a data processing system 472 (e.g., computer system) for storing and analyzing the measured data.

Having an instrument for measurements of local plasma parameters, such as the ion saturation current to the device and also the device surface temperature means having a better understanding and ultimately a better control over the entire etch process. Prior approaches for modern plasma diagnostics used across the semiconductor industry are represented mostly by traditional Langmuir probes, which provide a single-point measurement, while introducing significant disturbance to the processing plasma because of a supporting, wire-shielding alumina tube protruding deeply into the discharge chamber.

A multi-diagnostic device offers such unquestionable advantages as minimal disturbance to the process, simultaneous multi-point measurement and direct characterization of the etch rate profile. In one embodiment, external circuitry measures parameters associated with an individual module. In another embodiment, external circuitry measures the parameters associated with the modules at approximately the same time. In another embodiment, on board integrated circuitry measures one or all modules at nearly the same time. Data from the multi-diagnostic device provides immediate, in-situ information about radial and azimuthal non-uniformities (skews) in the etch rate characteristic for a specific tool. In-situ measurements of ion current and temperature at the surface of the multi-diagnostic device are very useful for solving chamber matching issues, as these measurements can help identify a source of a problem.

Reactive ion etch (RIE) processes commonly used in plasma-processing tools utilize the kinetic energy of Ar ions as well as chemical properties of other ion species (e.g. CF4) to remove (sputter) particles from the surface of the processed device. Ions are accelerated in the high-voltage sheath that forms at the biased rf electrode. In the case of two biased electrodes, the larger sheath with a higher voltage drop forms near the electrode with the smaller area commonly referred to as the “cathode.” The multi-diagnostic device is placed on top of the electrostatic chuck attached to the top of the cathode. The local fluxes of both chemically active and high-energy ions determine the etch rate at any given location on the multi-diagnostic device. Therefore, measurements of ion current to the multi-diagnostic device directly provide information from which the etch rate can be inferred. Coupled with theoretical models and measurements of the multi-diagnostic device potential (sheath voltage) and ion density in the plasma, the ion current data is used to determine electron temperature at the sheath edge, as well as the ion energy and angular distribution of each ion species at the multi-diagnostic device. This provides additional information from which one can predict (identify) the shape of the etched features.

Another critical piece of information the multi-diagnostic devices provides is the surface temperature distribution across the multi-diagnostic device. Direct multi-diagnostic device temperature measurements yield valuable diagnostic information. It is well known that substrate temperature has significant impact on plasma etching performance. Instability of substrate temperature during process can be linked to such issues as post-metal etch residues, undercut or sloping sidewall profiles and inconsistent photoresist selectivity.

Thus, by simultaneously measuring ion current and wafer temperature and potential distributions, one can separate the electrostatic chuck/backside helium cooling issues (leading to temperature non-uniformities) from plasma, i.e. source/bias issues (leading to ion current non-uniformities). This can be a critical piece of information for solving chamber-matching problems.

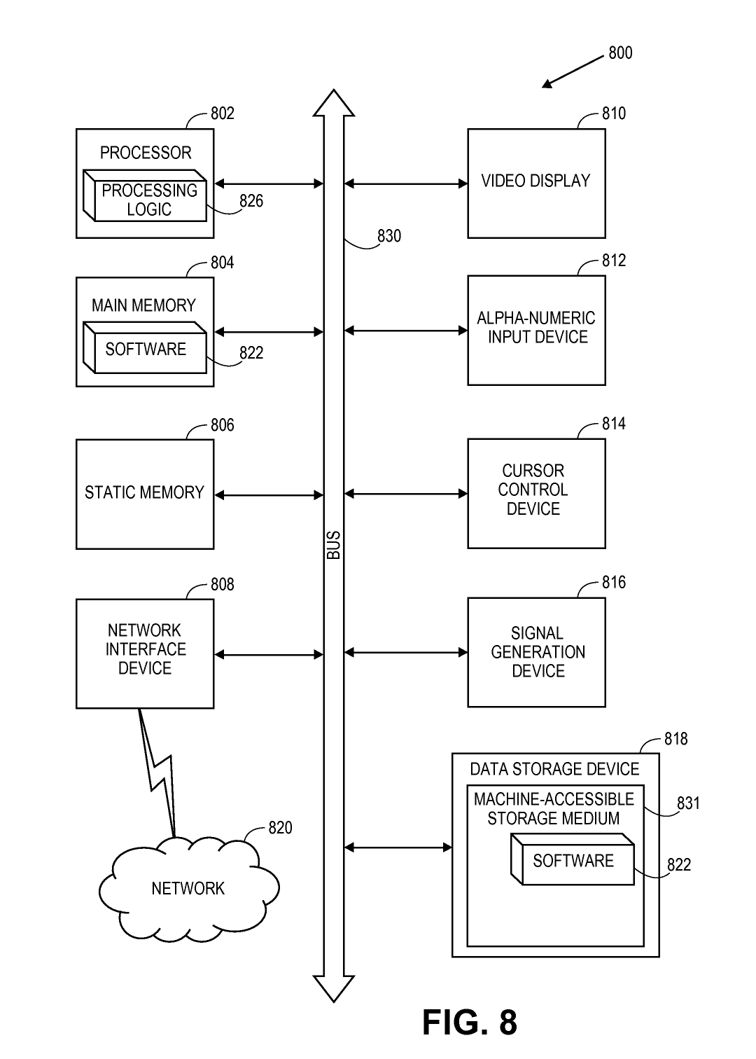

FIG. 8 illustrates a diagrammatic representation of a machine in the exemplary form of a computer system 800 within which a set of instructions, for causing the machine to perform any one or more of the methodologies discussed herein, may be executed. In alternative embodiments, the machine may be connected (e.g., networked) to other machines in a LAN, an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein.

The exemplary computer system 800 includes a processing device (processor) 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a data storage device 818, which communicate with each other via a bus 830.

Processor 802 represents one or more general-purpose processing devices such as a microprocessor, central processing unit, or the like. More particularly, the processor 802 may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processor 802 may also be one or more special-purpose processing devices such as an application specific integrated circuit (ASIC), a field programmable gate array (FPGA), a digital signal processor (DSP), network processor, or the like. The processor 802 is configured to execute the processing logic 826 for performing the operations and steps discussed herein.

The computer system 800 may further include a network interface device 808. The computer system 800 also may include a video display unit 810 (e.g., a liquid crystal display (LCD) or a cathode ray tube (CRT)), an alphanumeric input device 812 (e.g., a keyboard), a cursor control device 814 (e.g., a mouse), and a signal generation device 816 (e.g., a speaker).

The data storage device 818 may include a machine-accessible storage medium 831 on which is stored one or more sets of instructions (e.g., software 822) embodying any one or more of the methodologies or functions described herein. The software 822 may also reside, completely or at least partially, within the main memory 804 and/or within the processor 802 during execution thereof by the computer system 800, the main memory 804 and the processor 802 also constituting machine-accessible storage media. The software 822 may further be transmitted or received over a network 820 via the network interface device 808.

The machine-accessible storage medium 831 may also be used to store data structure sets that define user identifying states and user preferences that define user profiles. Data structure sets and user profiles may also be stored in other sections of computer system 800, such as static memory 806.

While the machine-accessible storage medium 831 is shown in an exemplary embodiment to be a single medium, the term “machine-accessible storage medium” should be taken to include a single medium or multiple media (e.g., a centralized or distributed database, and/or associated caches and servers) that store the one or more sets of instructions. The term “machine-accessible storage medium” shall also be taken to include any medium that is capable of storing, encoding or carrying a set of instructions for execution by the machine and that cause the machine to perform any one or more of the methodologies of the present invention. The term “machine-accessible storage medium” shall accordingly be taken to include, but not be limited to, solid-state memories, optical media, and magnetic media.

In the following description, numerous details are set forth. It will be apparent, however, to one skilled in the art, that the present invention may be practiced without these specific details. In some instances, well-known structures and devices are shown in block diagram form, rather than in detail, in order to avoid obscuring the present invention.

Some portions of the detailed description which follows are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussion, it is appreciated that throughout the description, calibrating discussions utilizing terms such as “processing”, “computing”, “calculating”, “determining”, “displaying” or the like, refer to the actions and processes of a computer system, or similar electronic computing device, that manipulates and transforms data represented as physical (e.g., electronic) quantities within the computer system's registers and memories into other data similarly represented as physical quantities within the computer system memories or registers or other such information storage, transmission or display devices.

The present invention also relates to an apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions.

The algorithms and displays presented herein are not inherently related to any particular computer or other apparatus. Various general purpose systems may be used with programs in accordance with the teachings herein, or it may prove convenient to construct a more specialized apparatus to perform the required method steps. The required structure for a variety of these systems will appear from the description below. In addition, the present invention is not described with reference to any particular programming language. It will be appreciated that a variety of programming languages may be used to implement the teachings of the invention as described herein.

A machine-readable medium includes any mechanism for storing or transmitting information in a form readable by a machine (e.g., a computer). For example, a machine-readable medium includes a machine readable storage medium (e.g., read only memory (“ROM”), random access memory (“RAM”), magnetic disk storage media, optical storage media, flash memory devices, etc.).

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A multi-diagnostic device located in a plasma processing environment, the device comprising:
a first array of sensors with each sensor having planar double probes;
a second array of sensors with each sensor having a resistor structure; and
circuitry, coupled to the first array of sensors and the second array of sensors, to measure ion saturation current to the device using the first array of sensors.

2. The device of claim 1, wherein the circuitry to measure potential distribution of the device using the first array of sensors of the first module.

3. The device of claim 1, wherein the circuitry to measure resistances of the second array of sensors of the second module to determine a temperature at a surface of the device.

4. The device of claim 1, wherein the circuitry is integrated with the device.

5. The device of claim 1, wherein each sensor of the first array of sensors is located on the device in proximity to a respective sensor of the second array of sensors.

6. The device of claim 1, wherein the circuitry further comprises a communication unit to transmit measurements to a system external to the plasma processing environment.

7. A method, comprising:
transferring a diagnostic device into a processing chamber having a plasma gas to perform diagnosis of the plasma; and
measuring ion saturation current to the device with a first array of sensors and on-board electronic circuitry.

8. The method of claim 7, further comprises measuring a device potential with the first array of sensors and the on-board electronic circuitry.

9. The method of claim 8, further comprises using the electronic circuitry to measure resistances of a second array of sensors each having a resistor structure to determine the temperature at the surface of the device.

10. The method of claim 9, wherein the diagnostic device is able to simultaneously or nearly simultaneously measure ion saturation current, device potential, and resistance to determine temperature at the surface of the device, from the sensors in order to diagnose and characterize the plasma.

11. A multi-diagnostic device located in a plasma processing environment, the device comprising:
a first array of sensors with each sensor having planar double probes;
a second array of sensors with each sensor having a resistor structure; and
circuitry coupled to the first array of sensors and the second array of sensors, the circuitry having a control unit to apply a first bias voltage to the first array of sensors and to acquire current data from the first array of sensors to determine ion saturation current to the device.

12. The device of claim 11, wherein the control unit to apply a second bias voltage to the second array of sensors.

13. The device of claim 11, wherein the control unit to acquire temperature data from the second array of sensors to determine a temperature at a surface of the device.

14. The device of claim 11, wherein each sensor of the first array of sensors includes planar double probes and each sensor of the second array of sensors includes a resistor structure.

15. The device of claim 13, wherein the control unit further comprises a first analog to digital converter (ADC) to digitize the acquired temperature data.

16. The device of claim 11, wherein the control unit to acquire voltage data from the first array of sensors to determine a potential distribution of the device.

17. The device of claim 16, wherein the control unit further comprises a second ADC to digitize the acquired current data and the voltage data.

18. The device of claim 11, wherein the control unit further comprises a first digital to analog converter (DAC) to generate a first voltage waveform in order to apply the first bias voltage.

19. The device of claim 12, wherein the control unit further comprises a second digital to analog converter (DAC) to generate a second voltage waveform in order to apply the second bias voltage.

20. The device of claim 11, wherein the circuitry further comprises:
a plurality of multiplexers to switch applied voltage between pads of the first and second arrays of sensors;
a plurality of operational amplifiers;
at least one direct current (dc) to dc converter;
a battery to provide a power supply; and
memory to store the measured data.
